(19) United States
(12) Patent Application Publication
(10) Pub. No.: US 2008/0073648 A1
(43) Pub. Date: Mar. 27, 2008

(54) THIN FILM TRANSISTOR ARRAY PANEL AND MANUFACTURING METHOD THEREOF

(75) Inventors: Tae-Young CHOI, Seoul (KR); Bo-Sung KIM, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/859,033

(22) Filed: Sep. 21, 2007

(30) Foreign Application Priority Data
Sep. 22, 2006 (KR) 1020060092322

(51) Int. Cl. H01L 51/10; H01L 29/04

(52) U.S. Cl. 257/72; 257/E51.005; 438/151

(57) ABSTRACT

A thin film transistor array panel includes a gate electrode formed on a substrate, a gate insulator covering the gate electrode, a source electrode including a first transparent material and disposed on the gate insulator, a drain electrode including a second transparent material and disposed on the gate insulator, and an organic semiconductor formed on the source and drain electrodes, and the gate insulator therebetween. The source electrode includes a first boundary opposing a second boundary of the drain electrode relative to the gate electrode, and the opposing boundaries overlap boundaries of the gate electrode with an alignment margin in the range of about −1 to +5 microns.

This application claims priority to Korean Patent Application No. 10-2006-0092322 filed on Sep. 22, 2006, and all the benefits accruing therefrom under 35 U.S.C. §119, the entire contents of which are incorporated herein by reference in its entirety.

### BACKGROUND OF THE INVENTION

(a) Field of the Invention

The present invention relates to a thin film transistor array panel and a manufacturing method thereof.

(b) Description of the Related Art

A flat panel display such as a liquid crystal display (“LCD”), an organic light emitting diode (“OLED”) display, and an electrophoretic display includes a pair of electric field generating electrodes and an electro-optical active layer disposed therebetween. The LCD includes a liquid crystal layer as the electro-optical active layer, and the OLED display includes an organic light emitting layer as the electro-optical active layer.

One of the pair of field generating electrodes is usually coupled with a switching element to receive electrical signals, and the electro-optical active layer converts the electrical signals into optical signals to display images.

The switching element for the flat panel display includes a thin film transistor (“TFT”) including three terminals, and gate lines transmitting control signals for controlling the TFTs and data lines transmitting data signals to be supplied for the pixel electrodes through the TFTs are also provided in the flat panel display.

Among the TFTs, organic thin film transistors (“OTFT”) are being vigorously developed. An OTFT includes an organic semiconductor instead of an inorganic semiconductor, such as Si.

Because the OTFT may be manufactured by a solution process at a low temperature, it may be easily adapted to a flat panel display with relatively large size, which may be not manufactured by a deposition process. Also, because the organic material has the characteristics that the organic material is made of patterns such as a fiber or a film, the OTFT is used as the core element of a flexible display device.

However, because of the contact resistance between the organic semiconductor and the signal lines connected thereto, the characteristics of the thin film transistors may be deteriorated.

### BRIEF SUMMARY OF THE INVENTION

An exemplary embodiment of a thin film transistor array panel provides a gate electrode formed on a substrate, a gate insulator covering the gate electrode, a source electrode including a first transparent material and disposed on the gate insulator, a drain electrode including a second transparent material and disposed on the gate insulator, and an organic semiconductor formed on the source and drain electrodes, and the gate insulator therebetween. The source electrode includes a first boundary opposing a second boundary of the drain electrode relative to the gate electrode, and the opposing boundaries overlap boundaries of the gate electrode with an alignment margin in a range of about −1 to +5 microns.

In an exemplary embodiment, the thin film transistor array panel may further include a first signal line formed on the substrate and connected to the source electrode, and a second signal line intersecting the first signal line and connected to the gate electrode.

In an exemplary embodiment, one of the boundaries of the gate electrode may be disposed on a same line with the opposing boundaries of the source and drain electrodes.

In an exemplary embodiment, the opposing boundaries of the source and drain electrodes may substantially overlap the boundaries of the gate electrode.

In an exemplary embodiment, the thin film transistor array panel may further include an interlayer insulating layer formed on the first and second signal lines and including an opening exposing the gate electrode.

In an exemplary embodiment, the gate insulator may be disposed in the opening of the interlayer insulating layer.

In an exemplary embodiment, the thin film transistor array panel may further include a pixel electrode electrically connected to the drain electrode.

In an exemplary embodiment, the thin film transistor array panel may further include a storage electrode line parallel to one of the first and second signal lines and include a portion overlapping the pixel electrode.

In an exemplary embodiment, the thin film transistor array panel may further include an interlayer insulating layer disposed between the storage electrode line and the pixel electrode.

In an exemplary embodiment, the thin film transistor array panel may further include a passivation member formed on the organic semiconductor.

An exemplary embodiment of a method of manufacturing a thin film transistor array panel provides forming a gate electrode on a substrate, forming a gate insulator covering the gate electrode, forming a source electrode and a drain electrode, each disposed on the gate insulator, the source electrode including a transparent material and a drain electrode opposing the source electrode, forming a partition including a first opening exposing portions of the source electrode and the drain electrode, and forming an organic semiconductor in the first opening. The source electrode includes a first boundary opposing a second boundary of the drain electrode relative to the gate electrode, and the opposing boundaries overlap boundaries of the gate electrode.

In an exemplary embodiment, an alignment margin of the opposing boundaries of the source and drain electrodes and the boundaries of the gate electrode may be in a range of about −1 to +5 microns.

In an exemplary embodiment, the method may further include forming a first signal line connected to the source electrode before forming the gate electrode and forming a second signal line intersecting the first signal line and including the gate electrode.

In an exemplary embodiment, the method may further include forming a pixel electrode electrically connected to the drain electrode.

In an exemplary embodiment, the method may further include forming a storage electrode line on a same layer as the first or second signal lines, parallel to the first or the second signal line, respectively, and overlapping the pixel electrode.

In an exemplary embodiment, the method may further include forming an interlayer insulating layer on the second signal line and forming a second opening exposing the gate electrode in the interlayer insulating layer.

In an exemplary embodiment, wherein one of the forming an interlayer insulating layer, the forming a gate insulator, the forming a partition, and the forming an organic semiconductor includes a solution process.

In an exemplary embodiment, the gate insulator may be formed in the second opening.

In an exemplary embodiment, one of the forming a gate insulator and the forming an organic semiconductor includes inkjet printing.

In an exemplary embodiment, the method may further include forming an interlayer insulating layer between the storage electrode line and the pixel electrode.

### BRIEF DESCRIPTION OF THE DRAWINGS

The present invention will become more apparent by describing embodiments thereof in detail with reference to the accompanying drawings, in which:

FIG. 1 is a layout view of an exemplary embodiment of an OTFT array panel according to the present invention;

FIG. 2 is a cross-sectional view of the OTFT array panel shown in FIG. 1 taken along line II-II;

FIGS. 3, 5, 7, 9, 11, 13, and 15 are layout views of the OTFT array panel shown in FIGS. 1 and 2 in intermediate steps of an exemplary embodiment of a manufacturing method thereof according to the present invention;

FIG. 4 is a cross-sectional view of the OTFT array panel shown in FIG. 3 taken along line IV-IV;

FIG. 6 is a cross-sectional view of the OTFT array panel shown in FIG. 5 taken along line VI-VI;

FIG. 8 is a cross-sectional view of the TFT array panel shown in FIG. 7 taken along line VIII-VIII;

FIG. 10 is a cross-sectional view of the OTFT array panel shown in FIG. 9 taken along line X-X;

FIG. 12 is a cross-sectional view of the OTFT array panel shown in FIG. 11 taken along line XII-XII;

FIG. 14 is a cross-sectional view of the TFT array panel shown in FIG. 13 taken along line XIV-XIV;

FIG. 16 is a cross-sectional view of the TFT array panel shown in FIG. 15 taken along line XVI-XVI;

FIG. 17 is a layout view of another exemplary embodiment of an OTFT array panel according to the present invention;

FIG. 18 is a cross-sectional view of the OTFT array panel shown in FIG. 17 taken along line XVIII-XVIII;

FIG. 19 is a layout view of another exemplary embodiment of an OTFT array panel according to the present invention; and

FIG. 20 is a cross-sectional view of the OTFT array panel shown in FIG. 19 taken along line XX-XX.

### DETAILED DESCRIPTION OF THE INVENTION

The present invention will be described more fully hereinafter with reference to the accompanying drawings, in which preferred embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower”, “under,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” relative to other elements or features would then be oriented “upper” or “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

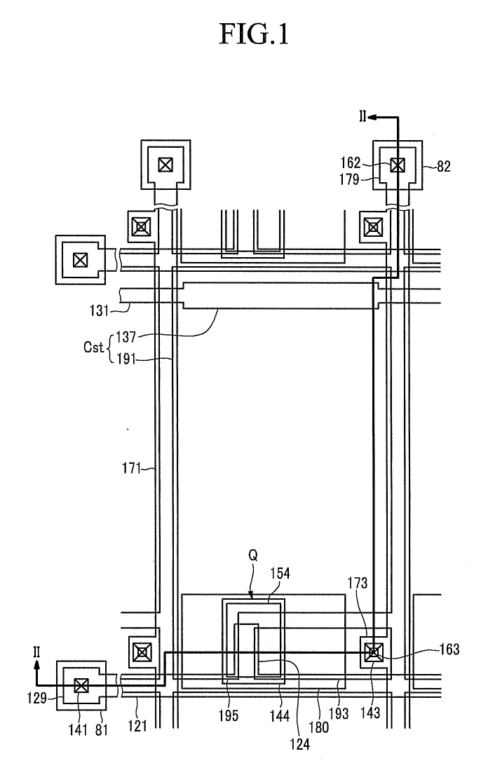

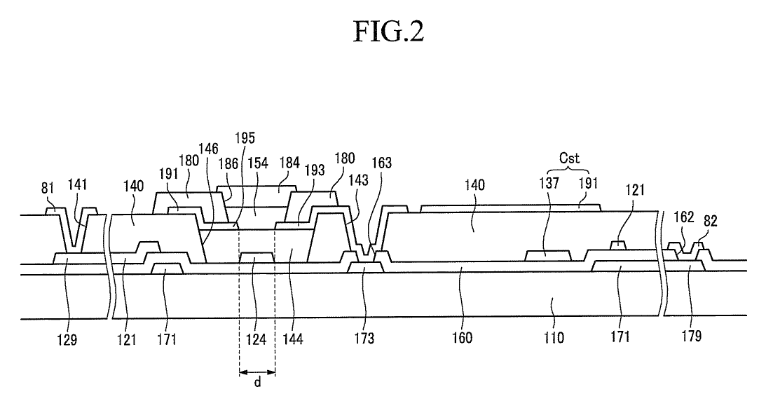

An OTFT array panel according to an exemplary embodiment of the present invention will be described with reference to FIGS. 1 and 2.

FIG. 1 is a layout view of an exemplary embodiment of an OTFT array panel according to the present invention, and FIG. 2 is a cross-sectional view of the OTFT array panel shown in FIG. 1 taken along line II-II.

As shown in FIGS. 1 and 2, a plurality of data lines 171 are formed on an insulating substrate 110. The insulating substrate 110 may be made of material such as transparent glass, silicone, or plastic.

The data lines 171 transmit data signals and extend substantially in a longitudinal direction. As described above, the data lines 171 are arranged in pairs. Each data line 171 includes a plurality of projections 173 protruding aside (e.g., in a transverse direction), and an end portion 179 having a relatively large area for contact with another layer or an external driving circuit. A data driving circuit (not shown) for generating the data signals may be mounted on a flexible printed circuit (“FPC”) film (not shown). In exemplary embodiments, the FPC may be attached to the substrate 110, directly mounted on the substrate 110, or integrated with the substrate 110. The data lines 171 may extend to connect to a driving circuit that may be integrated with the substrate 110. As used herein, “integrated” indicates formed to be a single unit or piece rather than combining separate elements.

In an exemplary embodiment, the data lines 171 are made of a metal including Al or an Al alloy, Ag or a Ag alloy, Au or a Au alloy, Cu or a Cu alloy, Mo or a Mo alloy, Cr, Ta, or Ti. The data lines 171 may have a multi-layered structure including two conductive films (not shown) having different physical characteristics.

Lateral sides of the data lines 171 are inclined relative to a surface (e.g., an upper surface) of the substrate 110. An inclination angle of the lateral sides of the data lines 171 may range from about 30 to 80 degrees.

A lower interlayer insulating layer 160 is formed on the data lines 171. The lower interlayer insulating layer 160 may be made of an inorganic insulator. In exemplary embodiments, the inorganic insulator may include silicon nitride (“SiNx”) and silicon oxide (“SiOx”). A thickness of the lower interlayer insulating layer 160 may be from about 2000 angstroms (Å) to about 4 microns.

The lower interlayer insulating layer 160 includes a plurality of contact holes 162 exposing the end portions 179 of the data lines 171 and a plurality of contact holes 163 exposing the projections 173 of the data lines 171.

A plurality of gate lines 121 and a plurality of storage electrode lines 131 are formed on the lower interlayer insulating layer 160.

The gate lines 121 transmit gate signals and extend substantially in a transverse direction to intersect the data lines 171. As described above, the gate lines 121 are arranged in pairs. Each of the gate lines 121 includes a plurality of gate electrodes 124 projecting upward (e.g., in the longitudinal direction away from the gate line 121 towards the storage electrode line 131), and an end portion 129 having a relatively large area for contact with another layer or an external driving circuit. A gate driving circuit (not shown) for generating the gate signals may be mounted on an FPC film (not shown). In exemplary embodiments, the FPC may be attached to the substrate 110, directly mounted on the substrate 110, or integrated with the substrate 110. The gate lines 121 may extend to connect to a driving circuit that may be integrated with the substrate 110.

The storage electrode lines 131 are supplied with a predetermined voltage and extend substantially parallel to the gate lines 121. Each of the storage electrode lines 131 is disposed between two adjacent gate lines 121 and is closer to the upper one of the two adjacent gate lines 121. Each of the storage electrode lines 131 includes a storage electrode 137 expanding upwards and downwards relative to a main portion of the storage electrode line 131. However, the storage electrode lines 131 are not limited thereto and may have various shapes and arrangements as is suitable for the purpose described herein.

The gate lines 121 and the storage electrode lines 131 may be made of a conductive material having low resistivity, such as that of the data lines 171.

Lateral sides of the gate lines 121 and the storage electrode lines 131 are inclined relative to a surface of the substrate 110 (e.g., an upper surface). Inclination angles of the lateral sides of the gate lines 121 and the storage electrode lines 131 range from about 30 to about 80 degrees.

An upper interlayer insulating layer 140 is formed on the gate lines 121 and the storage electrode lines 131. The upper interlayer insulating layer 140 may be made of an organic insulator. Exemplary embodiments of the organic insulator include, but are not limited to, a soluble high molecule compound such as a polyacryl compound, a polystyrene compound, and benzocyclobutane (BCB). A thickness of the insulating layer 140 may be from about 5000 Å to about 4 microns.

The upper interlayer insulating layer 140 is not disposed (e.g., is not formed) on the end portions 179 of the data lines 171 for reducing or effectively preventing detachment of the lower interlayer insulating layer 160 and the upper interlayer insulating layer 140 near the end portions 179 of the data lines 171 due to the poor adhesion between the layers 160 and 140. The upper interlayer insulating layer 140 is also not disposed on the end portions 179 of the data lines 171 for enhancing the adhesion between the end portions 179 of the data lines 171 and an external circuit.

The upper interlayer insulating layer 140 includes a plurality of openings 146 exposing the gate electrodes 124, a plurality of contact holes 141 exposing the end portions 129 of the gate lines 121, and a plurality of contact holes 143 exposing the contact holes 163 and the projections 173 of the data lines 171.

A plurality of gate insulators 144 are formed in the openings 146 of the upper interlayer insulating layer 140. The gate insulators 144 cover the gate electrodes 124 and have a thickness of about 1000 Å to about 10,000 Å. Sidewalls of the openings 146 are higher (e.g., thicker in a direction perpendicular to the upper surface of the substrate 110) than the gate insulators 144 such that the upper interlayer insulating layer 140 serves as a bank against the gate insulators 144. The openings 146 have a size (e.g., dimensions of height/thickness and width/area taken in a plane parallel to the upper surface of the substrate 110) that is sufficient to flatten the surfaces of the gate insulators 144.

The gate insulators 144 may be made of an inorganic insulator or an organic insulator. Exemplary embodiments of the organic insulator include a soluble high molecular compound such as a polyimide compound, a polyvinyl alcohol compound, and parylene. Exemplary embodiments of the inorganic insulator include silicon oxide that may have a surface treated with octadecyl-trichloro-silane (“OTS”).

A plurality of source electrodes 193, a plurality of pixel electrodes 191, and a plurality of contact assistants 81 and 82 are formed on the gate insulators 144 the upper interlayer insulating layer 140 and/or the lower interlayer insulating layer 160. In an exemplary embodiment, the source electrodes 193, pixel electrodes 191 and contact assistants 81 and 82 are made of a transparent conductor such as ITO, IZO or NiOx and have a thickness of about 300 Å to about 800 Å.

A difference in the work function between an organic semiconductor and the ITO layer or IZO layer may be small enough such that charge carriers can be effectively injected into the organic semiconductors from the source electrodes 193 and drain electrodes 195 that are made of ITO or IZO. When the difference in the work function therebetween is relatively small, a Schottky barrier generated between organic semiconductors 154 and the electrodes 193 and 195 may relatively easily allow the injection and transport of the charge carriers.

The source electrodes 193 are connected to the projections 173 of the data lines 171 through the contact holes 143 and extend onto the gate electrodes 124.

Each of the pixel electrodes 191 includes a drain electrode 195 disposed on a gate insulator 144 and opposite a source electrode 193 with respect to a gate electrode 124.

An interval between parallel boundaries of the source electrodes 193 and the drain electrodes 195 disposed on the gate electrodes 124 is the same as a width “d” of the gate electrodes 124, such that the opposing boundaries of the source and drain electrodes 193 and 195 relative to the gate electrode 124 overlap the boundaries of the gate electrodes 124. At least one boundary of the gate electrode 124 is disposed on a same line with a boundary of the opposing boundaries of the source and drain electrodes 193 and 195. An alignment margin between the boundaries of the gate electrode 124, and the opposing boundaries of the source and drain electrodes 193 and 195 is in the range of from −1 to +5 microns. As used herein, the positive value of the alignment margin means that the gate electrodes 124 overlap the source and drain electrodes 193 and 195, and the negative value means that the gate electrodes 124 do not overlap the source and drain electrodes 193 and 195.

The pixel electrodes 191 include a plurality of portions overlapping at least the portions of the storage electrode lines 131 including the storage electrodes 137 for reinforcing a voltage storage capacity of a storage capacitor Cst.

The storage capacitor Cst includes a pixel electrode 191, a storage electrode line 131 and the upper interlayer insulating layer 140 therebetween With the structure of the illustrated embodiment, the storage electrode lines 131 overlapping the pixel electrodes 191 are arranged such that the electrostatic capacity of the liquid crystal capacitor may be improved. Advantageously, the storage electrode lines 131 overlapping the pixel electrodes 191 reduce or effectively prevent decrease of the ratio of Ion/Ioff due to the material limit of the organic semiconductor 154.

The pixel electrodes 191 overlap the gate lines 121 and the data lines 171 to increase the aperture ratio.

The contact assistants 81 and 82 are connected to the end portions 129 of the gate lines 121 and the end portions 179 of the data lines 171 through the contact holes 141 and 162, respectively. The contact assistants 81 and 82 protect the end portions 129 and 179 and enhance the adhesion between the end portions 129 and 179 and external devices (not shown).

A plurality of partitions 180 are formed on the source electrodes 193, the pixel electrodes 191, and the upper interlayer insulating layer 140 as illustrated in FIG. 2.

The partitions 180 include a plurality of openings 186 disposed on the gate electrodes 124 and the openings 146 of the upper interlayer insulating layer 140 for exposing portions of the source electrodes 193 and the drain electrodes 195, and the portions of the gate insulators 144 between the source electrodes 193 and the drain electrodes 195.

The partitions 180 may be made of a photosensitive organic material that can be solution-processed. A thickness of the partitions 180 may range from about 5000 Å to about 4 microns.

The openings 186 of the partitions 180 are smaller than the openings 146 of the upper interlayer insulating layer 140 disposed thereunder. Therefore, the partitions 180 fix the gate insulators 144 to reduce or effectively prevent lifting of the gate insulators 144 and infiltration of the gate insulators 144 by chemicals used in manufacturing processes.

A plurality of organic semiconductor islands 154 are formed in the openings 186 of the partitions 180. The organic semiconductor islands 154 are disposed on the gate electrodes 124 and contact the source electrodes 193 and the drain electrodes 195. A height (e.g., thickness or distance taken in a direction perpendicular to the insulating substrate 110) of the organic semiconductor islands 154 is smaller than that of the upper partitions 180 such that the semiconductor islands 154 are completely confined in the upper partitions 180. Since lateral surfaces of the organic semiconductor islands 154 are not exposed, infiltration of chemicals used in later process steps to the organic semiconductor islands 154 is reduced or effectively prevented.

In exemplary embodiments, the organic semiconductor islands 154 may include a high molecular compound or a low molecular compound that is soluble in an aqueous solution or an organic solvent. When the organic semiconductor islands 154 include a low molecular compound that is soluble in an aqueous solution or an organic solvent, the organic semiconductor islands 154 can be formed by a printing method, such as by inkjet printing. The organic semiconductor islands 154 may be formed by a solution process, such as spin coating, slit coating, or deposition process. In an alternative embodiment, the partitions 180 may be omitted in the deposition process.

The organic semiconductor islands 154 may be made of, or from derivatives of, tetracene or pentacene with a substituent. Alternatively, the organic semiconductor islands 154 may be made of an oligothiophene including four to eight thiophenes connected at the positions 2 and 5 of thiophene rings.

The organic semiconductor islands 154 may be made of polythienylenevinylene, poly 3-hexylthiophene, polythiophene, phthalocyanine, or metallized phthalocyanine or halogenated derivatives thereof. Alternatively, the organic semiconductor islands 154 may be made of perylene tetracarboxylic dianhydride (“PTCDA”), naphthalene tetracarboxylic dianhydride (NTCDA), or their imide derivatives. The organic semiconductor islands 154 may also be made of perylene, coronene, or derivatives thereof with a substituent.

In an exemplary embodiment t thickness of the organic semiconductor islands 154 may be in the range of about 300 to 3,000 angstroms.

A gate electrode 124, a source electrode 193, a drain electrode 195, and an organic semiconductor island 154 form an organic TFT (“OTFT”) Q (FIG. 1). The TFT Q includes a channel formed in the organic semiconductor island 154 disposed between the source electrode 193 and the drain electrode 195. In an exemplary embodiment, when opposing sides of the source electrode 193 and the drain electrode 195 are curved, a width of the OTFT Q may be maximized such that current characteristics of the OTFT may be improved.

The pixel electrodes 191 receive data voltages from the organic TFT Q and generate an electric field in conjunction with a common electrode (not shown) of an opposing display panel (not shown) that is supplied with a common voltage. The electric field determines orientations of liquid crystal molecules (not shown) in a liquid crystal layer (not shown) disposed between the pixel electrode 191 and common electrode. The pixel electrode 191 and the common electrode form a capacitor referred to as a “liquid crystal capacitor,” which stores applied voltages even after the organic TFT turns off.

A plurality of passivation members 184 are formed on the organic semiconductor islands 154. In an exemplary embodiment, the passivation members 184 may be made of a fluorine hydrocarbon compound or a polyvinyl alcohol compound. The passivation members 184 protect the organic semiconductor islands 154 from external heat, plasma, and chemicals.

In the OTFT array panel of the illustrated embodiment of FIGS. 1 and 2, because the gate electrodes 124 are only disposed between the opposing drain and source electrodes 193 and 195, portions where the source and drain electrodes 193 and 195 and the organic semiconductor islands 154 are contacted to each other do not overlap the gate electrodes 124. Therefore, the light incident from a back light (a light source) under the substrate 110 transmits through the source and drain electrodes 193 and 195, which are made of a transparent material, and arrives in the lower surfaces of the organic semiconductor islands 154 contacted to the source and drain electrodes 193 and 195. Advantageously, photo carriers are rapidly increased in the lower surfaces of the organic semiconductor islands 154 contacted to the source and drain electrodes 193 and 195, such that the contact resistance between the organic semiconductor islands 154 and the source and drain electrodes 193 and 195 may be minimized, and the characteristics of the OTFT may be improved.

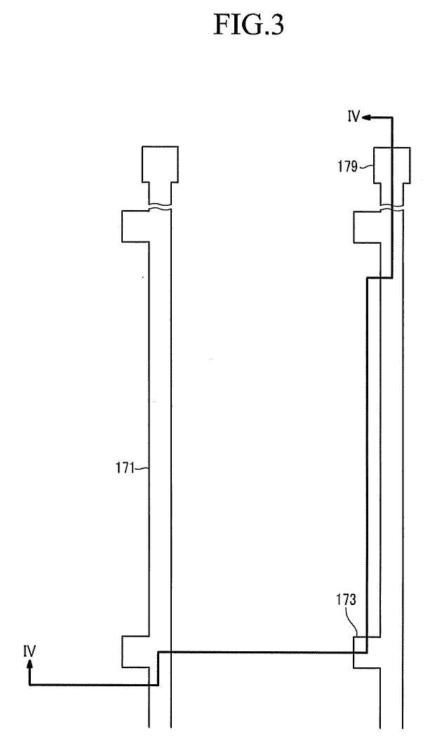

Now, an exemplary embodiment of a method of manufacturing the OTFT array panel shown in FIGS. 1 and 2 according to the present invention will be described in detail with reference to FIGS. 3-16 as well as FIGS. 1 and 2.

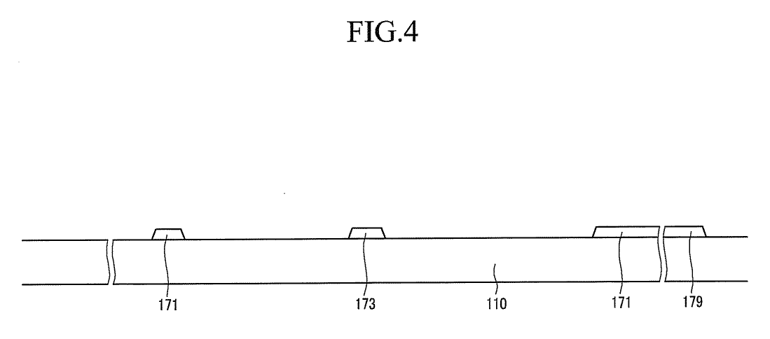

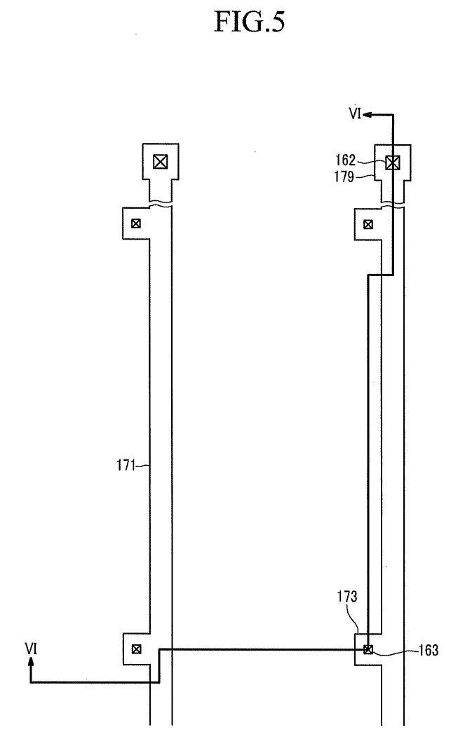

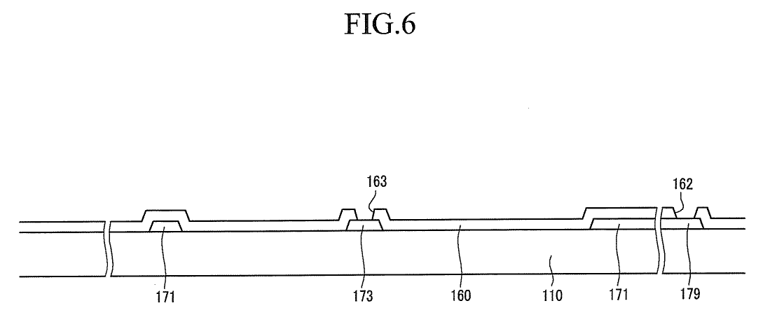

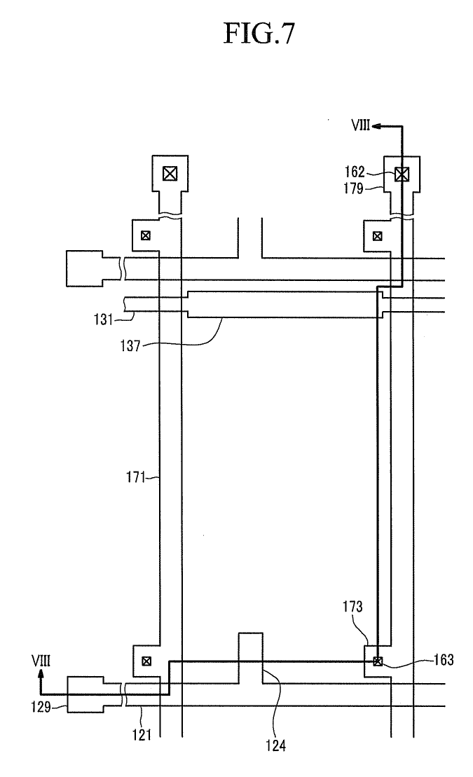

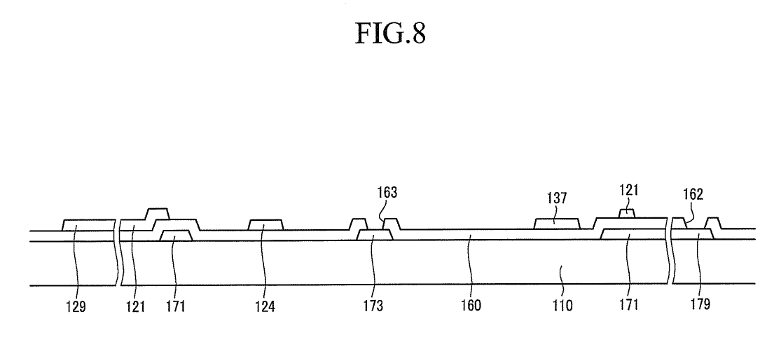

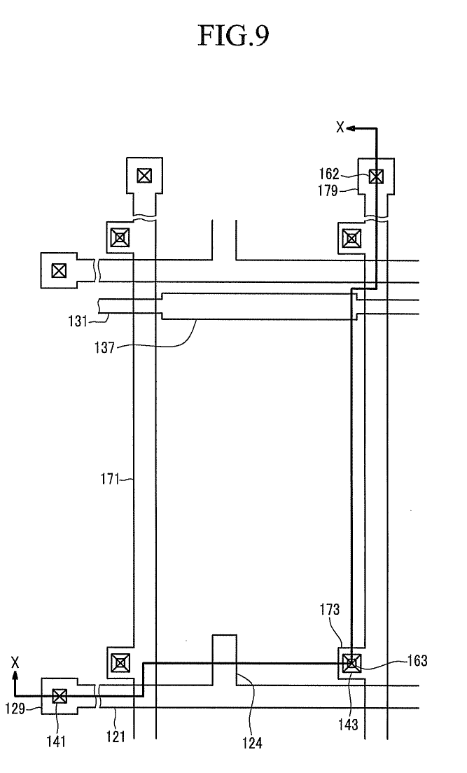

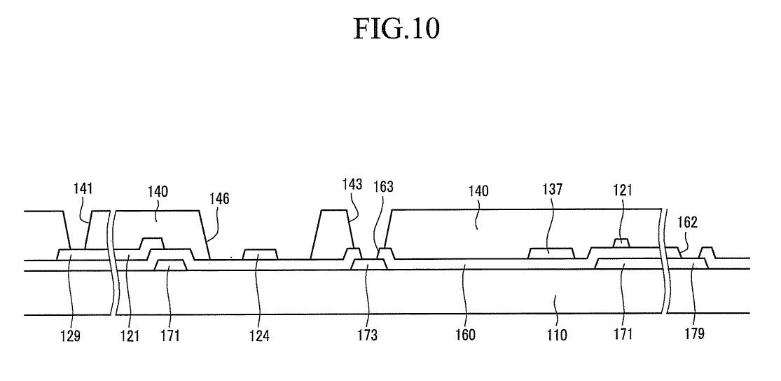

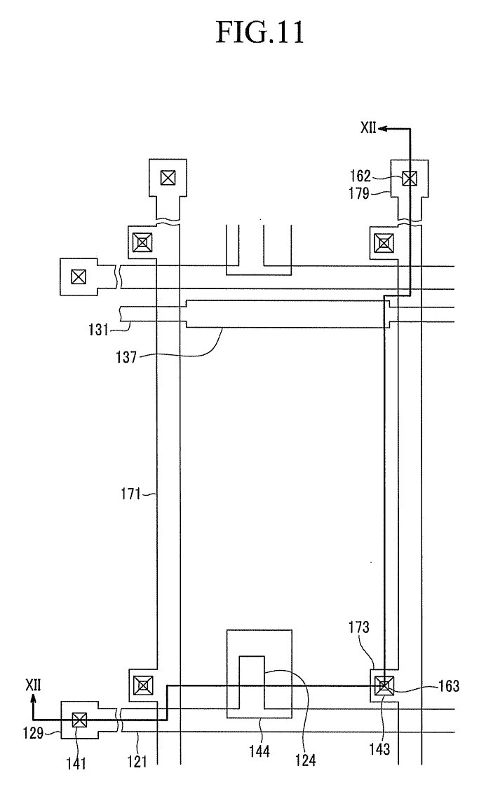

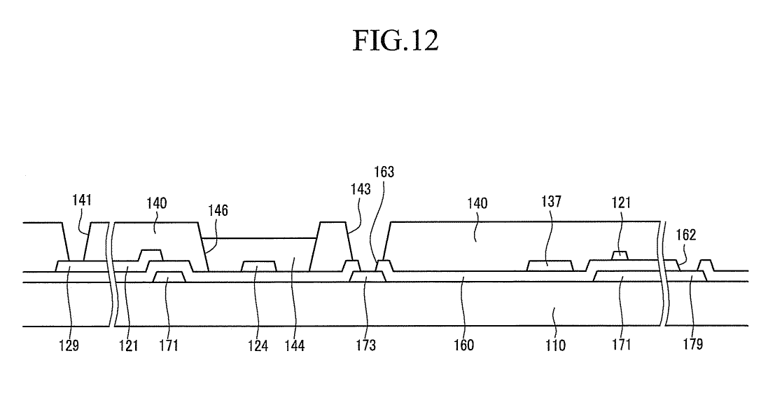

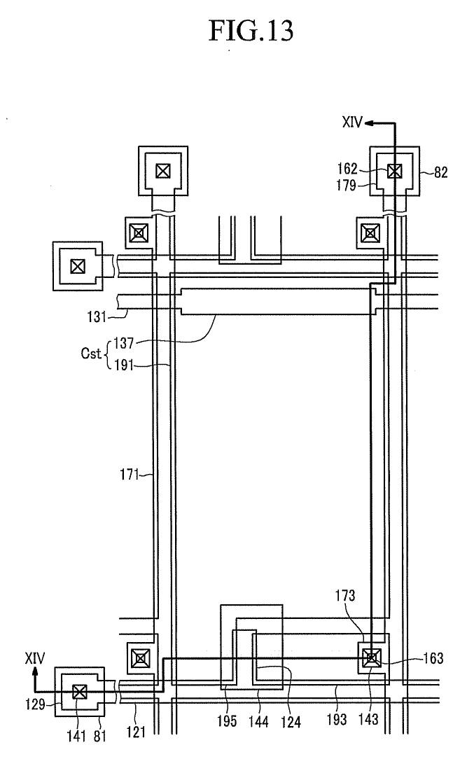

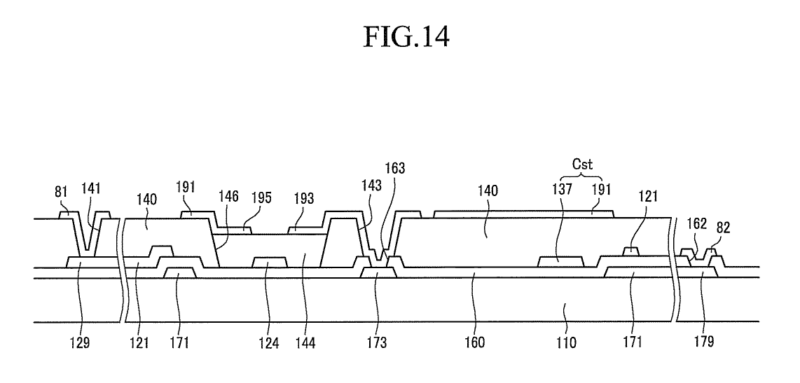

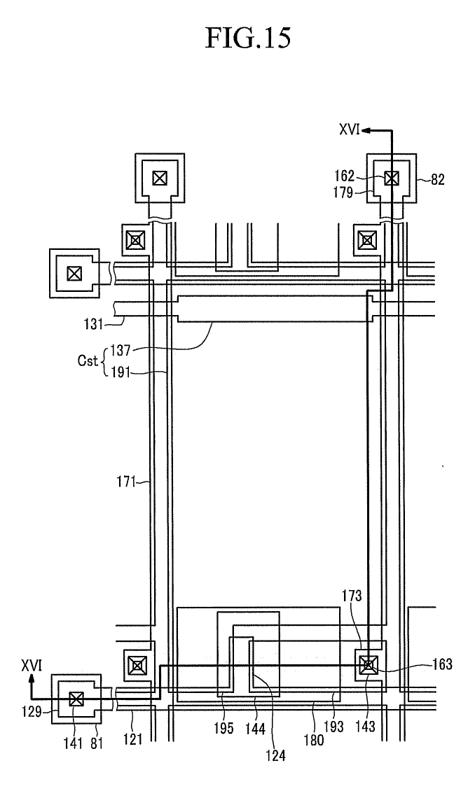

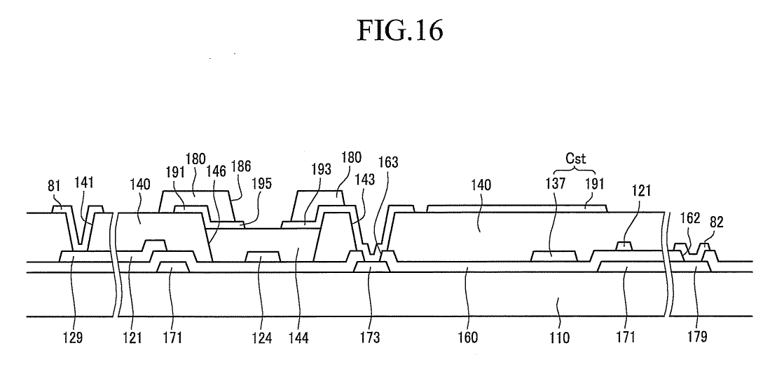

FIGS. 3, 5, 7, 9, 11, 13, and 15 are layout views of the OTFT array panel shown in FIGS. 1 and 2 in intermediate steps of an exemplary embodiment of a manufacturing method thereof according to the present invention, FIG. 4 is a cross-sectional view of the OTFT array panel shown in FIG. 3 taken along line IV-IV, FIG. 6 is a cross-sectional view of the OTFT array panel shown in FIG. 5 taken along line VI-VI, FIG. 8 is a cross-sectional view of the TFT array panel shown in FIG. 7 taken along line VIII-VIII, FIG. 10 is a cross-sectional view of the OTFT array panel shown in FIG. 9 taken along line X-X, FIG. 12 is a cross-sectional view of the OTFT array panel shown in FIG. 11 taken along line XII-XII, FIG. 14 is a cross-sectional view of the TFT array panel shown in FIG. 13 taken along line XIV-XIV, and FIG. 16 is a cross-sectional view of the TFT array panel shown in FIG. 15 taken along line XVI-XVI.

Referring to FIGS. 3 and 4, a conductive layer is deposited on a substrate 110, such as by sputtering, etc. The deposited conductive layer is patterned, such as by lithography and etching to form a plurality of data lines 171. The data lines 171 include projections 173 and end portions 179.

Referring to FIGS. 5 and 6, a lower interlayer insulating layer 160, including a plurality of contact holes 162 and 163, is formed, such as by deposition and patterning. In one exemplary embodiment, the deposition of the lower interlayer insulating layer 160 may be performed by CVD of an inorganic material.

As shown in FIGS. 7 and 8, a conductive layer is deposited on the lower interlayer insulating layer 160 and patterned, such as by lithography and etching, to form a plurality of gate lines 121. The gate lines 121 include gate electrodes 124, end portions 129 and a plurality of storage electrode lines 131. The storage electrode lines 131 include a plurality of storage electrodes 137.

Referring to FIGS. 9 and 10, a photosensitive organic insulating film is deposited, such as by spin-coating and patterned to form an upper interlayer insulating layer 140. The upper interlayer insulating layer 140 includes a plurality of openings 146 and a plurality of contact holes 141 and 143. Portions of the photosensitive organic insulating film near the end portions 179 of the data lines 171 are fully removed.

Referring to FIGS. 11 and 12, a plurality of gate insulators 144 are formed in the openings 146 of the upper interlayer insulating layer 140, such as by inkjet printing, etc. In one exemplary embodiment, the inkjet printing includes dripping and drying of a solution. However, the invention is not limited thereto and the gate insulators 144 may be formed by any of a number of various other solution processes, such as by spin coating and slit coating.

Referring to FIGS. 13 and 14, an amorphous ITO layer is deposited, such as by sputtering, etc., and patterned, such as by lithography and etching, to form a plurality of source electrodes 193, a plurality of pixel electrodes 191 including drain electrodes 195, and a plurality of contact assistants 81 and 82.

In exemplary embodiments, the sputtering of the amorphous ITO layer may be performed at a low temperature of about 25° C. to about 130° C. In one exemplary embodiment, the sputtering of the amorphous ITO layer is performed at room temperature. The etching of the amorphous ITO layer may be wet etching with a relatively weak alkaline etchant. The low temperature and the weak alkaline etchant may reduce damage to the gate insulators 144 and the upper interlayer insulating layer 140 caused by heat and chemicals.

Parallel boundaries of the source electrodes 193 and the drain electrodes 195 (e.g., outer boundaries relative to the gate electrode 124) disposed on the gate electrodes 124 substantially overlap both boundaries of the gate electrodes 124. In one exemplary embodiment the opposing boundaries of the source and drain electrodes 193 and 195 are aligned to the boundaries of the gate electrodes 124, and at least one boundary of the gate electrode 124 is disposed on the same line with the opposing boundaries of the source and drain electrodes 193 and 195 (FIG. 2). As used herein, “substantially overlapping” may include an overlap of about 5 microns.

In one exemplary embodiment, an alignment margin between the boundaries of the gate electrodes 124, and the boundaries of the source and drain electrodes 193 and 195 is in the range of from −1 to +5 microns. A positive value of the alignment margin means that the gate electrodes 124 overlap the source and drain electrodes 193 and 195, and a negative value means that the gate electrodes 124 do not overlap the source and drain electrodes 193 and 195.

Referring to FIGS. 15 and 16, a photosensitive insulating layer is coated, and subjected to light exposure and developing to form a plurality of partitions 180 including a plurality of openings 186.

Referring to FIGS. 1 and 2, a plurality of organic semiconductor islands 154 and a plurality of passivation members 184 are sequentially formed in the openings 186. Forming of the organic semiconductor islands 154 and the plurality of passivation members 184 may include inkjet printing, etc.

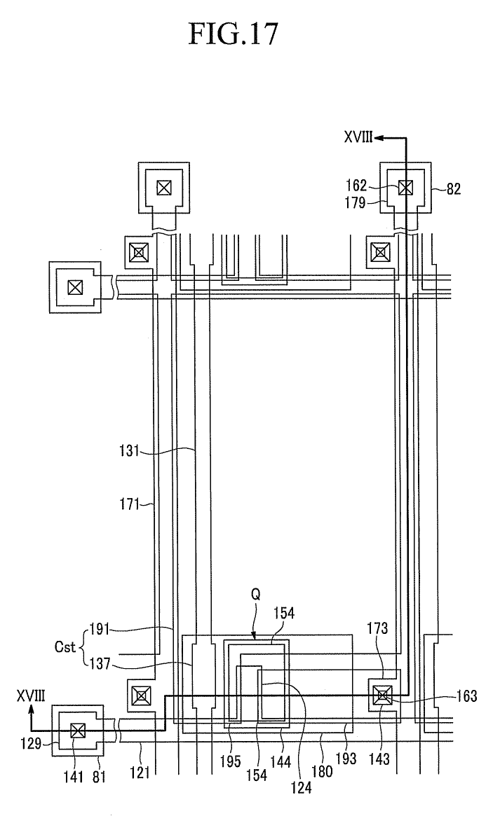

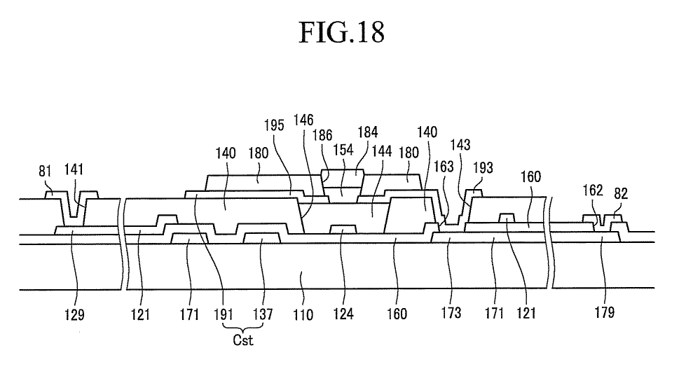

Another exemplary embodiment of an OTFT array panel for a liquid crystal display according to the present invention will be described in detail with reference to FIGS. 17 and 18.

FIG. 17 is a layout view of another exemplary embodiment of an OTFT array panel according to the present invention, and FIG. 18 is a cross-sectional view of the OTFT array panel shown in FIG. 17 taken along line XVIII-XVIII.

The same reference numerals corresponding to the same or like parts as those described in FIGS. 1-16 and same descriptions corresponding to the previous embodiment are omitted.

As shown in FIGS. 17 and 18, a plurality of data lines 171 and a plurality of storage electrode lines 131 are formed on a substrate 110.

The storage electrode lines 131 are formed on the same layer as the data lines 171, and parallel to the data lines 171, unlike the illustrated embodiment of FIGS. 1 and 2, where the storage electrode lines 131 extended in a transverse direction and perpendicular to the data lines 171.

The data lines 171 transmit data signals and extend substantially in a longitudinal direction. Each data line 171 includes a plurality of projections 173 protruded aside, and an end portion 179 having a large area for contact with another layer or an external driving circuit (not shown).

As illustrated in FIG. 17, the storage electrode lines 131 transmit a predetermined voltage such as a common voltage and extend in the longitudinal direction. Each storage electrode line 131 is disposed between two adjacent data lines 171, and closer to a left one of the two data lines 171. The storage electrode line 131 includes a plurality of storage electrodes 137 extended to the left and right of a main portion of the storage electrode line 131 (e.g., aside of the storage electrode line 131). However, the invention is not limited thereto and the storage electrode lines 131 may have various shapes and arrangements as is suitable for the purpose described herein.

A lower interlayer insulating layer 160 is formed on the data lines 171 and storage electrode lines 131. In an exemplary embodiment, the lower interlayer insulating layer 160 may be made of an inorganic insulator such as silicon nitride (“SiNx”) and silicon oxide (“SiOx”).

The lower interlayer insulating layer 160 includes a plurality of contact holes 162 exposing the end portions 179 of the data lines 171, and a plurality of contact holes 163 exposing the projections 173 of the data lines 171.

A plurality of gate lines 121 are formed on the lower interlayer insulating layer 160.

The gate lines 121 transmit gate signals and extend substantially in a transverse direction. Each of the gate lines 121 intersects the data lines 171 and the storage electrode lines 131. The gate lines 121 include a plurality of gate electrodes 124 projecting upward and an end portion 129 having a relatively large area for contact with another layer or an external driving circuit (not shown).

An upper interlayer insulating layer 140 is formed on the gate lines 121. IN an exemplary embodiment, the upper insulating layer 140 may be made of an organic insulator having a good solubility polymer such as polyacryl, polystyrene, and benzocyclobutene (BCB).

As illustrated in FIG. 18, a portion of the upper interlayer insulating layer 140 neighboring the end portions 179 of the data lines 171 is removed.

The upper interlayer insulating layer 140 includes a plurality of openings 146 exposing the gate electrodes 124, a plurality of contact holes 141 exposing the end portions 129 of the gate lines 121, and a plurality of contact holes 143 exposing the projections 173 of the data line 171 through the contact holes 163 of the lower interlayer insulating layer 160.

A plurality of gate insulators 144 are formed in the openings 146 of the upper interlayer insulating layer 140.

A plurality of source electrodes 193, a plurality of pixel electrodes 191, and a plurality of contact assistants 81 and 82 are formed on the upper interlayer insulating layer 140, the lower interlayer insulating layer 160 and the gate insulators 144.

The source electrodes 193 are electrically connected to the data lines 171 through the contact holes 143 and 163. The source electrodes 193 are extended to the upper portion of the gate electrodes 124 as illustrated in FIG. 17.

Each pixel electrode 191 includes a portion 195 disposed opposite a source electrode 193 with respect to a gate electrode 124. This portion of the pixel electrode 191 is referred to as the drain electrode 195. Opposing boundaries (e.g., outer boundaries) of the source and drain electrodes 193 and 195 are disposed on the gate electrodes 124 and overlap the boundaries of the gate electrodes 124. An alignment margin between the boundaries of the gate electrodes 124 and the opposing outer boundaries of the source and drain electrodes 193 and 195 may be in a range of about −1 to +5 microns.

An additional capacitor called a “storage capacitor,” and connected in parallel to the liquid crystal capacitor, is provided for enhancing the voltage storing capacity. The storage capacitors are implemented by overlapping the pixel electrodes 191 with the storage electrode lines 131, including the storage electrodes 137, via the lower and upper interlayer insulating layers 160 and 140.

Unlike the previous illustrated embodiments, when the lower interlayer insulating layer 160 made of inorganic material is used as the dielectric substance of the storage capacitor, the storage capacitance may be improved.

The pixel electrodes 191 overlap the gate lines 121 and the data lines 171 to increase the aperture ratio.

The contact assistants 81 and 82 are connected to the end portions 129 and 179 of the gate lines 121 and the data lines 171 through the contact holes 141 and 162, respectively.

A plurality of partitions 180 are formed on the source electrodes 193, the pixel electrodes 191, and the upper interlayer insulating layer 140. The partitions 180 include a plurality of openings 186 disposed over the gate electrodes 124 and the openings 146 of the upper interlayer insulating layer 140 for exposing portions of the source electrodes 193 and the drain electrodes 195 and portions of the gate insulators 144 therebetween.

A plurality of organic semiconductor islands 154 and a plurality of passivation members 184 are placed in the openings 186 of the partitions 180.

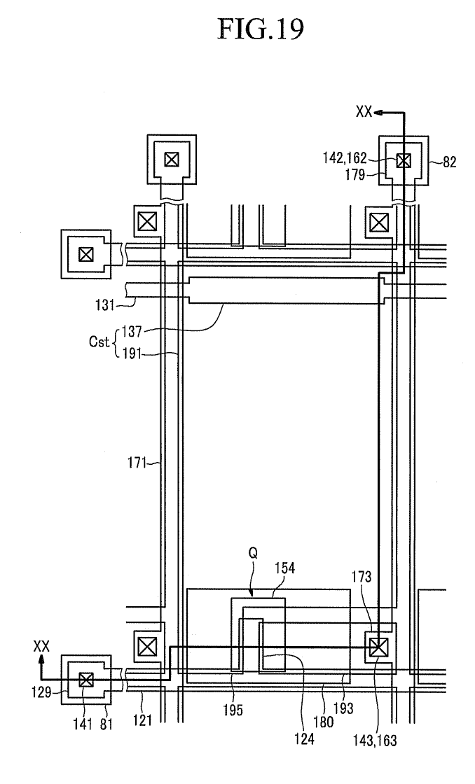

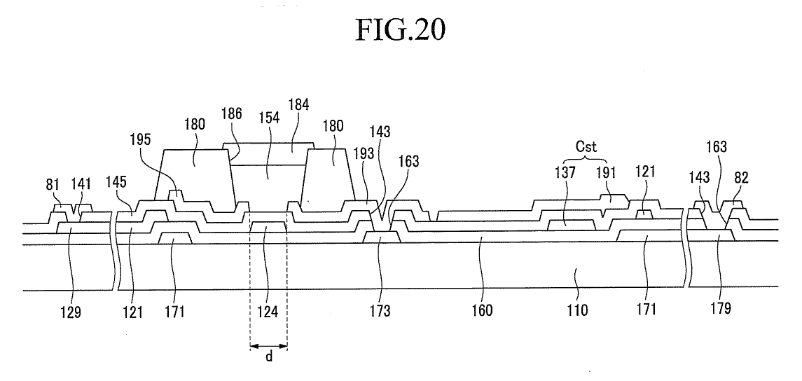

Another exemplary embodiment of an OTFT array panel for a liquid crystal display according to the present invention will be described in detail with reference to FIGS. 19 and 20.

FIG. 19 is a layout view of another exemplary embodiment of an OTFT array panel according to the present invention, and FIG. 20 is a cross-sectional view of the OTFT array panel shown in FIG. 19 taken along line XX-XX.

The same reference numerals corresponding to the same or like parts as those described in FIGS. 1-18 and same descriptions corresponding to the previous embodiments are omitted.

Layered structures of the OTFT array panel illustrated in FIGS. 19 and 20 are almost the same as those shown in FIGS. 1 and 2.

A plurality of data lines 171 transmitting data signals and including a plurality of projections 173 protruding aside (e.g., towards the left and outward from a main portion of the data line 171) and an end portion 179 having a relatively large area for contact with another layer or an external driving circuit (not shown) are formed on an insulating substrate 110. The insulating substrate 110 may be made of material such as transparent glass, silicone, or plastic.

A lower interlayer insulating layer 160 is formed on the data lines 171. The lower interlayer insulating layer 160 may include a plurality of contact holes 162 exposing the end portions 179 of the data lines 171 and a plurality of contact holes 163 exposing the projections 173 of the data lines 171.

A plurality of gate lines 121 transmitting gate signals and including a plurality of gate electrodes 124 projecting upward and an end portion 129 having a relatively large area for contact with another layer or an external driving circuit (not shown), and a plurality of storage electrode lines 131 including a storage electrode 137 expanding upward and downward are formed on the lower interlayer insulating layer 160.

A gate insulator 145 is wholly formed on the gate lines 121 and the storage electrode lines 131. The gate insulator 145 includes a plurality of contact holes 141 exposing the end portions 129 of the gate lines 121, and a plurality of contact holes 143 and 142 exposing the projections 173 of the data lines 171 and the end portions 179 of the data lines 171, respectively.

In an exemplary embodiment, the gate insulator 145 may not be disposed on the end portions 179 of the data lines 171 and/or may have a substantially flat surface (e.g., upper surface) according to the manufacturing method. The gate insulator 145 may be made of an inorganic insulator, such as silicon nitride and silicon oxide, or an organic insulator.

A plurality of source electrodes 193, a plurality of pixel electrodes 191, and a plurality of contact assistants 81 and 82 are formed on the gate insulator 145.

An interval between the parallel (e.g., opposing outer) boundaries of the source electrodes 193 and the drain electrodes 195 disposed on the gate electrodes 124 are substantially the same as the width “d” of the gate electrodes 124 as illustrated in FIGS. 20, such that the opposing boundaries of the source and drain electrodes 193 and 195 overlap the boundaries of the gate electrodes 124. An alignment margin between the boundaries of the gate electrodes 124, and the opposing boundaries of the source and drain electrodes 193 and 195 may be in a range of about −1 to +5 microns.

A plurality of partitions 180 are formed on portions of the source electrodes 193, the drain electrodes 195, the pixel electrodes 191, and the gate insulator 145.

The partitions 180 include a plurality of openings 186 disposed on the gate electrodes 124 for exposing portions of the source electrodes 193 and the drain electrodes 195, and the portions of the gate insulators 145 therebetween.

A plurality of organic semiconductor islands 154 and a plurality of passivation members 184 are sequentially formed in the openings 186 of the partitions 180.

As in the illustrated embodiment, because the contact resistance between the organic semiconductor islands 154, and the source and drain electrodes 193 and 195 may be minimized, the characteristics of the OTFT may be improved. As the organic semiconductors 154 are formed after forming the conductive layers and the insulating layers, the organic semiconductors 154 may be protected from external heat and chemicals in the manufacturing process. Furthermore, the partitions 180 and the passivation members 184 defining the regions of the organic semiconductors 154 are formed such that influence upon the organic semiconductor islands 154 may be minimized in the manufacturing process.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A thin film transistor array panel comprising:
a gate electrode formed on a substrate;
a gate insulator covering the gate electrode;
a source electrode including a first transparent material and disposed on the gate insulator;
a drain electrode including a second transparent material and disposed on the gate insulator; and
an organic semiconductor formed on the source and drain electrode and the gate insulator therebetween,
wherein the source electrode includes a first boundary opposing a second boundary of the drain electrode relative to the gate electrode, the opposing boundaries overlapping boundaries of the gate electrode with an alignment margin in a range of about −1 to +5 microns.

2. The thin film transistor array panel of claim 1, further comprising:
a first signal line formed on the substrate and connected to the source electrode; and
a second signal line intersecting the first signal line and connected to the gate electrode.

3. The thin film transistor array panel of claim 1, wherein one of the boundaries of the gate electrode is disposed on a same line with the opposing boundary of the source electrode or the drain electrode.

4. The thin film transistor array panel of claim 1, wherein the opposing boundaries of the source and drain electrodes substantially overlap the boundaries of the gate electrode.

5. The thin film transistor array panel of claim 2, further comprising an interlayer insulating layer formed on the first and second signal lines and including an opening exposing the gate electrode.

6. The thin film transistor array panel of claim 5, wherein the gate insulator is disposed in the opening of the interlayer insulating layer.

7. The thin film transistor array panel of claim 2, further comprising a pixel electrode electrically connected to the drain electrode.

8. The thin film transistor array panel of claim 2, further comprising a storage electrode line parallel to the first signal line or the second signal line, the storage electrode line including a portion overlapping the pixel electrode.

9. The thin film transistor array panel of claim 8, further comprising an interlayer insulating layer disposed between the storage electrode line and the pixel electrode.

10. The thin film transistor array panel of claim 2, further comprising a passivation member formed on the organic semiconductor.

11. A method of manufacturing a thin film transistor array panel, the method comprising:
forming a gate electrode on a substrate;
forming a gate insulator covering the gate electrode;
forming a source electrode and a drain electrode, each of the source electrode and the drain electrode disposed on the gate insulator, the source electrode including a transparent material and the drain electrode opposing the source electrode;
forming a partition including a first opening exposing portions of the source electrode and the drain electrode; and
forming an organic semiconductor in the first opening,
wherein the source electrode includes a first boundary opposing a second boundary of the drain electrode relative to the gate electrode, the opposing boundaries overlapping boundaries of the gate electrode.

12. The method of claim 11, wherein an alignment margin of the opposing boundaries of the source and drain electrodes and the boundaries of the gate electrode is in a range of about −1 to +5 microns.

13. The method of claim 12, further comprising:
forming a first signal line connected to the source electrode before the forming a gate electrode; and
forming a second signal line intersecting the first signal line and including the gate electrode.

14. The method of claim 11, further comprising;
forming a pixel electrode electrically connected to the drain electrode.

15. The method of claim 14, further comprising:
forming a storage electrode line on a same layer as the first or second signal lines parallel to the first or second signal line, respectively, and overlapping the pixel electrode.

16. The method of claim 15, further comprising:
forming an interlayer insulating layer on the second signal line; and
forming a second opening exposing the gate electrode in the interlayer insulating layer.

17. The method of claim 16, wherein at least one of the forming an interlayer insulating layer, the forming a gate insulator, the forming a partition, and the forming an organic semiconductor includes a solution process.

18. The method of claim 17, wherein the gate insulator is formed in the second opening.

19. The method of claim 18, wherein at least one of the forming a gate insulator and the forming an organic semiconductor includes inkjet printing.

20. The method of claim 15, further comprising:
forming an interlayer insulating layer between the storage electrode line and the pixel electrode.
